(19) United States
(12) Patent Application Publication
(10) Pub. No.: US 2024/0107711 A1
(43) Pub. Date: Mar. 28, 2024

(54) ELECTRONIC DEVICE

(71) Applicant: NIDEC CORPORATION, Kyoto (JP)

(72) Inventor: Takeru INAYOSHI, Kyoto (JP)

(21) Appl. No.: 18/474,226

(22) Filed: Sep. 26, 2023

(30) Foreign Application Priority Data
Sep. 27, 2022 (JP) 2022-153475

(51) Int. Cl. H05K 7/20

(52) U.S. Cl. CPC H05K 7/2039; H05K 7/20154; H05K 7/20336

(57) ABSTRACT

According to one aspect of the present invention, a plurality of heat elements, a plurality of heat sinks, at least one of which is attached to each of the heat elements, a cooling device that feeds a fluid in contact with a surface of the heat sink and promotes heat radiation of the heat sink by the fluid, and a heat pipe connected to the plurality of heat sinks are provided.

### CROSS-REFERENCE TO RELATED APPLICATIONS

The present invention claims priority under 35 U.S.C. § 119 to Japanese Patent Application No. 2022-153475 filed on Sep. 27, 2022, the entire content of which is incorporated herein by reference.

### FIELD OF THE INVENTION

The present invention relates to an electronic device.

### BACKGROUND

In an electronic device having a plurality of heat generating components, a plurality of fans generate a flow of air in a housing to cool the heat generating components. In such an electronic device, when the air blowing amount of a part of the fans decreases, a region in which the flow velocity of the air locally decreases is generated in the housing, which may cause insufficient cooling of a part of the heat generating components. Conventionally, there is known a configuration in which a plenum chamber generates a uniform air flow independent of an air blowing amount of an individual fan in a housing, and the air blowing amount of another fan is increased to compensate for a decrease in the air blowing amount of some fans.

In the conventional structure, there is a problem that a space in a housing is greatly used to generate an equal flow of air, and an electronic device becomes complicated and large.

### SUMMARY

According to one aspect of the present invention, a plurality of heat elements, a plurality of heat sinks, at least one of which is attached to each of the heat elements, a cooling device that feeds a fluid in contact with a surface of the heat sink and promotes heat radiation of the heat sink by the fluid, and a heat pipe connected to the plurality of heat sinks are provided.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of an electronic device according to a first embodiment;

FIG. 2 is an exploded view of a first heat generator of the first embodiment;

FIG. 3 is a diagram schematically illustrating a configuration of the electronic device according to the first embodiment;

FIG. 4 is a diagram schematically illustrating a configuration of an electronic device according to a second embodiment;

FIG. 5 is a diagram schematically illustrating a configuration of an electronic device according to a third embodiment;

FIG. 6 is a diagram schematically illustrating a configuration of an electronic device according to a fourth embodiment;

FIG. 7 is a diagram schematically illustrating a configuration of an electronic device according to a fifth embodiment; and

FIG. 8 is a perspective view of a heat sink and a heat pipe according to a sixth embodiment.

### DETAILED DESCRIPTION

Hereinafter, embodiments of the present invention will be described with reference to the drawings.

Each drawing illustrates a first direction D1, a second direction D2, and a third direction D3. The first direction D1, the second direction D2, and the third direction D3 are directions orthogonal to each other. Hereinafter, each part of an electronic device 1 will be described based on the first direction D1, the second direction D2, and the third direction. In the following description, the direction of each unit of the electronic device 1 may be described with one side (+D3 side) in the third direction as the upper side. However, the posture of the electronic device 1 at the time of use is an example, and is not limited to the following embodiment.

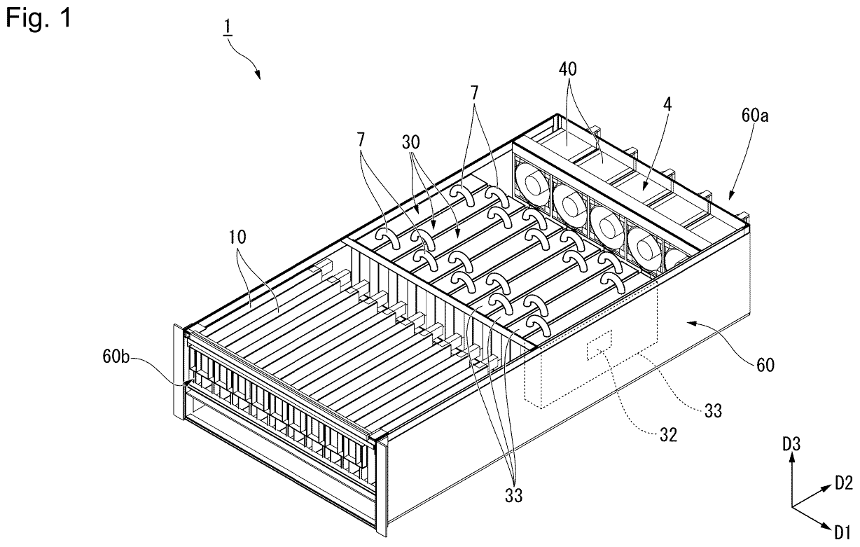

FIG. 1 is a perspective view of the electronic device 1 according to a first embodiment. The electronic device 1 of the present embodiment is a calculation server. However, the application of the electronic device 1 is not limited to the present embodiment.

The electronic device 1 includes a plurality of first heat generators 30, a plurality of second heat generators 10, a cooling device 4, a plurality of heat pipes 7, and a housing 60 that houses these components. In FIG. 1, the housing 60 is illustrated in a state where the upper lid portion is removed.

The housing 60 has a box shape with the first direction D1, the second direction D2, and the third direction D3 as respective plane directions. The housing 60 is made of, for example, a metal material.

The housing 60 is provided with an exhaust port 60a and an intake port 60b. The exhaust port 60a is provided at an end portion on one side (+D2 side) in the second direction of the housing 60. The intake port 60b is provided at an end portion on the other side (−D2 side) in the second direction of the housing 60. The exhaust port 60a and the intake port 60b are provided by opening side walls on both sides in the second direction of the housing 60. The air is taken into the housing 60 from the intake port 60b and discharged to the outside of the housing 60 at the exhaust port 60a. The air flows from the other side (−D2 side) in the second direction toward one side (+D2 side) in the second direction in the housing 60.

The plurality of first heat generators 30 are arranged in the first direction D1 in the housing 60. The electronic device 1 according to the present embodiment is provided with ten first heat generators 30. The first heat generator 30 has a substantially rectangular parallelepiped shape. A slight gap is provided between the first heat generators 30 arranged in the first direction D1. The gap between the first heat generators 30 may be closed by a sheet-like member.

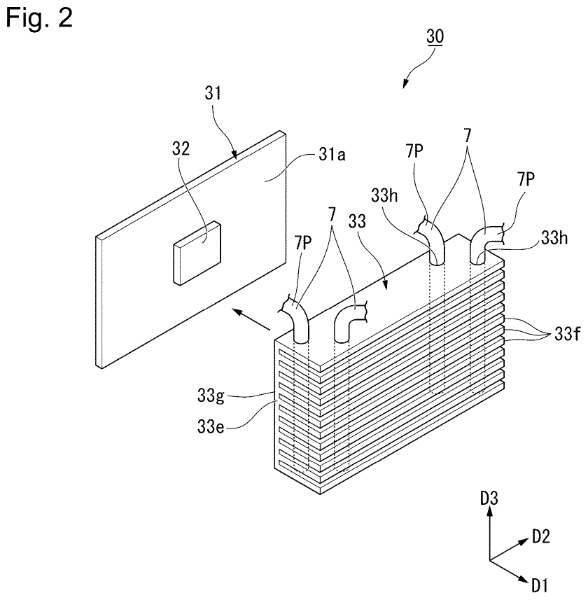

FIG. 2 is an exploded view of the first heat generator 30.

The first heat generator 30 includes a board 31, a heat element 32, and a heat sink 33. That is, the electronic device 1 includes the plurality of boards 31, the plurality of heat elements 32, and the plurality of heat sinks 33.

The board 31 is a rigid board, and a circuit is provided on the surface and inside. The board 31 has a mounting surface 31a extending along a direction orthogonal to the first direction D1. The mounting surface 31a faces one side (+D1 side) in the first direction. The heat element 32 is mounted on the mounting surface 31a. In addition, another element may be mounted on the board 31.

The board 31 may be connected to the board 31 of another first heat generator 30. In this case, the boards 31 are connected to each other via a main board (not illustrated) or the like. The main board is located on the other side (−D3 side) in the third direction with respect to the board 31 and extends along a plane orthogonal to the third direction D3.

The heat element 32 is an image processing element such as a graphics processing unit (GPU). However, the type of the heat element 32 is not limited as long as it is an element that generates heat in accordance with driving. In addition to the heat element 32 described above, another heat element may be mounted on the board 31.

The heat sink 33 is made of a metal material having high heat conductivity such as an aluminum alloy. At least one heat sink 33 is attached to each heat element 32. The heat sink 33 includes a base plate 33e and a plurality of fins 33f.

The base plate 33e extends along the mounting surface 31a of the board 31. That is, the base plate 33e extends along a direction orthogonal to the first direction D1. The base plate 33e has a heat absorbing surface 33g facing the other side (−D1 side) in the first direction. The heat absorbing surface 33g faces the heat element 32. The heat absorbing surface 33g may be in direct contact with the heat element 32 or may be in contact with the heat element 32 via a flowable heat transfer material such as heat radiation grease. In either case, the heat of the heat element 32 is transferred to the heat absorbing surface 33g of the heat sink 33.

The plurality of fins 33f are provided on the surface on one side (+D1 side) in the first direction of the base plate 33e. Each of the fins 33f has a rectangular shape. Each of the fins 33f extends along a plane orthogonal to the third direction D3. The plurality of fins 33f are arranged along the third direction D3 with a gap interposed therebetween. That is, the heat sink 33 has a plurality of fins 33f arranged in one direction (the third direction D3 in the present embodiment). The air generated by the cooling device 4 to be described later passes between the fins 33f. As a result, the heat transferred from the heat element 32 to the heat sink 33 is transferred to the air. That is, the heat sink 33 dissipates the heat of the heat element 32.

The fin 33f is provided with a through hole 33h. The heat pipe 7 passes through the through hole 33h. Since the four heat pipes 7 are connected to the fins 33f of the present embodiment, four through holes 33h are provided in one fin 33f. The through holes 33h of the plurality of fins 33f arranged in the third direction D3 overlap each other when viewed from the third direction D3.

The heat pipe 7 extends along one direction (in the present embodiment, the third direction) and penetrates and is connected to the plurality of fins 33f of the heat sink 33. The heat pipe 7 is joined to the inner peripheral edge of the through hole 33h of the fin 33f by brazing, for example.

The heat pipe 7 includes a sealed container 7P in a sealed pipe shape and a working fluid filled in the sealed container 7P in a depressurized state. A capillary structure (wick) is provided on the inner wall of the sealed container 7P of the heat pipe 7. The heat pipe 7 causes heat transfer from the high-temperature portion to the low-temperature portion by circulation of the working fluid inside. The working fluid is vaporized by absorbing heat at the high-temperature portion of the sealed container 7P. The vaporized working fluid moves to the low-temperature portion through the cavity in the sealed container 7P. The working fluid cooled in the low-temperature portion is aggregated to return to the liquid, is absorbed by the wick, and returns to the high-temperature portion along the wick.

In the present embodiment, the heat pipe 7 in which the sealed container 7P has a pipe shape has been described, but the sealed container 7P is not limited to a pipe shape as long as the sealed container 7P performs a similar function. As an example, the sealed container may have a sheet shape in which a working fluid is filled between a pair of plate members stacked in the thickness direction. In this case, the heat pipe 7 can be described as a configuration called a vapor chamber. That is, in the present specification, the vapor chamber is one form of the heat pipe 7 having a different structure of the sealed container 7P. The heat pipe 7 in the present specification may be a heat transfer element having a working fluid that transfers heat by phase change and a sealed container 7P that is filled with the working fluid.

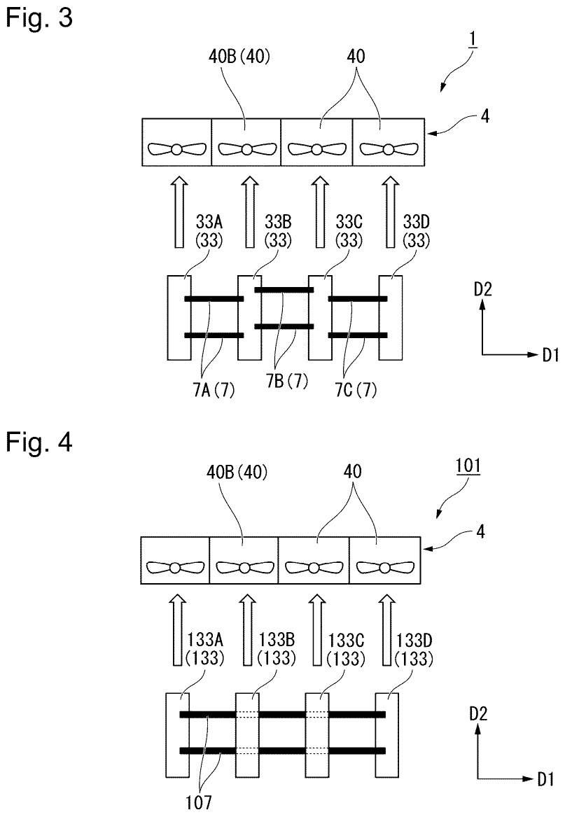

As illustrated in FIG. 1, the heat pipe 7 connects the heat sinks 33 adjacent to each other in the first direction D1. That is, the heat pipes 7 are connected to the plurality of heat sinks 33. The heat pipes 7 transfer heat of the heat sinks 33 to be connected to each other. A connection configuration between the plurality of heat pipes 7 and the plurality of heat sinks 33 will be described in detail later with reference to FIG. 3.

As illustrated in FIG. 1, the second heat generator 10 is disposed on the other side (−D2 side) in the second direction with respect to the first heat generator 30. The plurality of second heat generators 10 are arranged in the first direction D1 in the housing 60. The electronic device 1 according to the present embodiment is provided with ten second heat generators 10. The second heat generator 10 includes a heat element (not illustrated) similarly to the first heat generator 30. The calorific value of the heat element of the second heat generator 10 is smaller than the calorific value of the heat element 32 of the first heat generator 30.

The cooling device 4 is disposed at an end portion on one side (+D2) in the second direction in the housing 60. Therefore, the cooling device 4 is located on one side (+D2 side) in the second direction with respect to the first heat generator 30. The cooling device 4 covers the exhaust port 60a.

The cooling device 4 has a plurality of fans 40. In the present embodiment, the cooling device 4 is provided with five fans 40. The plurality of fans 40 are arranged along the first direction D1. Each of the plurality of fans 40 is an axial fan that takes in air from the other side (−D2 side) in the second direction and sends air to one side (+D2 side) in the second direction. As a result, the cooling device 4 generates an airflow in the second direction D2 inside the housing 60. Note that the fan 40 is not limited to an axial fan as long as it generates an airflow in the second direction D2 in the housing 60, and may be another type of fan such as a centrifugal fan.

The airflow generated by the action of the cooling device 4 causes the air to enter the housing 60 from the outside of the housing 60 through the intake port 60b. Further, the air passes through the inside of the housing 60 in the order of the second heat generator 10 and the first heat generator 30, and is blown out of the housing 60 through the cooling device 4 and the exhaust port 60a. This air cools the second heat generator 10 in the process of passing around the second heat generator 10, and cools the first heat generator 30 in the process of passing around the first heat generator 30.

According to the present embodiment, among the first heat generator 30 and the second heat generator 10, the first heat generator 30 having a relatively large calorific value is disposed downstream of the second heat generator 10 having a relatively small calorific value. That is, the plurality of heat generators 10 and 30 are arranged in the order of increasing calorific value along the direction of the airflow in the housing 60. As a result, the air warmed by the first heat generator 30 having a large calorific value does not warm the second heat generator 10, and the heat generators 10 and 30 can be reliably cooled. Although not illustrated here, another heat generator may be disposed between the first heat generator 30 and the second heat generator 10 in the second direction. In this case, the calorific value of the heat generator is preferably larger than the calorific value of the second heat generator 10 and smaller than the calorific value of the first heat generator 30.

FIG. 3 is a diagram modeling a connection configuration between the plurality of heat pipes 7 and the plurality of heat sinks 33 according to the present embodiment. Here, the description will be given assuming that the electronic device 1 is modeled and includes four fans 40 and four heat sinks 33. Here, the four heat sinks 33 are parts of different first heat generators 30. Therefore, the four heat sinks 33 are attached to different heat elements 32.

The electronic device 1 of FIG. 3 includes, as the plurality of heat pipes 7, two first heat pipes 7A, two second heat pipes 7B, and two third heat pipes 7C. In addition, the electronic device 1 includes, as the plurality of heat sinks 33, a first heat sink 33A, a second heat sink 33B, a third heat sink 33C, and a fourth heat sink 33D. The first heat sink 33A, the second heat sink 33B, the third heat sink 33C, and the fourth heat sink 33D are arranged in this order toward one side (+D side) in the first direction. Each heat sink 33 faces the fan 40 in the second direction.

The two first heat pipes 7A extend in parallel with each other. The first heat pipe 7A is connected to the first heat sink 33A and the second heat sink 33B. As a result, the first heat pipe 7A transfers heat between the first heat sink 33A and the second heat sink 33B.

The two second heat pipes 7B extend in parallel with each other. The second heat pipe 7B is disposed to be shifted in the second direction D2 with respect to the first heat pipe 7A and the third heat pipe 7C in order to suppress interference with the first heat pipe 7A and the third heat pipe 7C. The second heat pipe 7B is connected to the second heat sink 33B and the third heat sink 33C. As a result, the second heat pipe 7B transfers heat between the second heat sink 33B and the third heat sink 33C.

The two third heat pipes 7C extend in parallel with each other. The third heat pipe 7C is connected to the third heat sink 33C and the fourth heat sink 33D. As a result, the third heat pipe 7C transfers heat between the third heat sink 33C and the fourth heat sink 33D.

Here, as an example, a case where the air blowing amount of the fan 40B facing the second heat sink 33B in the second direction D2 decreases will be considered. When the air blowing amount of by the fan 40B decreases, the amount of air flowing between the fins 33f of the facing second heat sinks 33B decreases, and the amount of heat dissipated from the second heat sinks 33B decreases. In this case, there is a concern that the cooling of the heat element 32 attached to the second heat sink 33B becomes insufficient. Note that, in the present specification, a case where the air blowing is stopped and the air blowing amount becomes zero is also assumed as a state where the “air blowing amount decreases”.

First, in the electronic device 1 according to the present embodiment, the plurality of fans 40 and the plurality of heat sinks 33 are arranged in the first direction D1 and face each other in the second direction D2. Therefore, when the air blowing amount of one fan 40B decreases, the pressure of the airflow passing through the second heat sink 33B facing the fan 40B decreases. As a result, the airflow of the fans 40 on both sides in the first direction D1 flows to the second heat sink 33B side, and a decrease in the heat radiation amount of the second heat sink 33B is suppressed.

In the present embodiment, the second heat sink 33B is connected to the first heat sink 33A by the two first heat pipes 7A, and is connected to the third heat sink 33C by the two second heat pipes 7B. When the heat radiation amount of the second heat sink 33B decreases, the temperature of the second heat sink 33B becomes higher than the temperatures of the first heat sink 33A and the third heat sink 33C. This causes a temperature difference between both end portions of the first heat pipe 7A and the second heat pipe 7B, so that the first heat pipe 7A transfers heat from the second heat sink 33B to the first heat sink 33A, and the second heat pipe 7B transfers heat from the second heat sink 33B to the third heat sink 33C. This heat transfer continues until the temperatures of the first heat sink 33A, the second heat sink 33B, and the third heat sink 33C become uniform. In addition, due to this action, the temperature of the third heat sink 33C becomes higher than the temperature of the fourth heat sink 33D, and the heat of the third heat sink 33C moves to the fourth heat sink 33D via the third heat pipe 7C.

According to the present embodiment, the heat pipes 7 connect the plurality of heat sinks 33. Therefore, when the heat radiation amount to the air of the specific heat sink 33 decreases, heat can be transferred from the heat sink 33 to the other heat sink 33 via the heat pipe 7. As a result, insufficient cooling of the heat element 32 attached to the specific heat sink 33 can be suppressed, and a highly reliable electronic device can be provided.

According to the present embodiment, three or more heat sinks 33 are connected via the heat pipes 7, respectively. Therefore, when the heat radiation amount of one heat sink 33 decreases, the heat radiation can be compensated by the other two or more heat sinks 33, and the reliability of cooling can be enhanced. According to the present embodiment, it is possible to suppress an increase in size and complexity of the electronic device 1 in order to enhance reliability of cooling, and it is possible to realize a highly reliable cooling structure with a simple structure.

In the present embodiment, one heat pipe 7 is connected to the heat sink 33 at both end portions thereof. That is, since the heat pipes 7 are connected to the heat sinks 33 only at both end portions, the arrangement of the heat pipes 7 can be easily simplified, and the degree of freedom in the arrangement of the heat sinks 33 can be further increased.

In the present embodiment, the case where the cooling device 4 feeds air as a fluid to cool the heat sink 33 has been described. However, the cooling device 4 may have a plurality of pumps for sending a liquid such as cooling water as a fluid. In this case, the heat sink is disposed in the flow path of the cooling water pumped by the pump. That is, the cooling device 4 is only required to prompt the heat radiation of the heat sink 33 by feeding the fluid in contact with the surface of the heat sink 33.

FIG. 4 is a diagram schematically illustrating a connection configuration between a plurality of heat pipes 107 and a plurality of heat sinks 133 of an electronic device 101 according to the second embodiment. In the description of each embodiment below, the same reference numerals are given to the same components as those of the embodiment already described, and the description thereof will be omitted.

The electronic device 101 includes two heat pipes 107. In addition, the electronic device 101 includes, as the plurality of heat sinks 133, a first heat sink 133A, a second heat sink 133B, a third heat sink 133C, and a fourth heat sink 133D. The first heat sink 133A, the second heat sink 133B, the third heat sink 133C, and the fourth heat sink 133D are arranged in this order toward one side (+D side) in the first direction. Each heat sink 133 faces the fan 40 in the second direction.

The two heat pipes 107 extend in parallel with each other. The two heat pipes 107 are connected to the first heat sink 133A, the second heat sink 133B, the third heat sink 133C, and the fourth heat sink 133D, respectively. That is, according to the present embodiment, three or more heat sinks 133 are connected via one heat pipe 107. Therefore, when the heat radiation amount of one heat sink 133 decreases, the heat radiation can be compensated by the other two or more heat sinks 133, and the reliability of cooling can be enhanced.

In the present embodiment, since one heat pipe 107 connects three or more heat sinks 133, the number of contact points between the heat pipes 107 and the heat sinks 133 in the heat transfer path can be reduced as compared with the case of using two or more heat pipes, and heat transfer efficiency can be enhanced.

Here, similarly to the above-described embodiment, the effect of the present embodiment will be specifically described on the basis of a case where the air blowing amount of the fan 40B facing the second heat sink 133B and the second direction D2 decreases. In this case, the amount of heat dissipated from the second heat sink 133B decreases, and the temperature of the second heat sink 133B becomes higher than the temperatures of the other heat sinks 133.

The second heat sink 133B is connected to the first heat sink 133A, the third heat sink 133C, and the fourth heat sink 133D by the heat pipe 107. Therefore, the heat of the second heat sink 133B is directly transferred not only to the first heat sink 133A and the second heat sink 133B but also to the fourth heat sink 133D. According to the present embodiment, the heat of one heat sink 133 can be simultaneously transferred to three or more other heat sinks 133, the heat transfer efficiency can be increased, and the temperature rise of the heat element 32 can be more quickly suppressed.

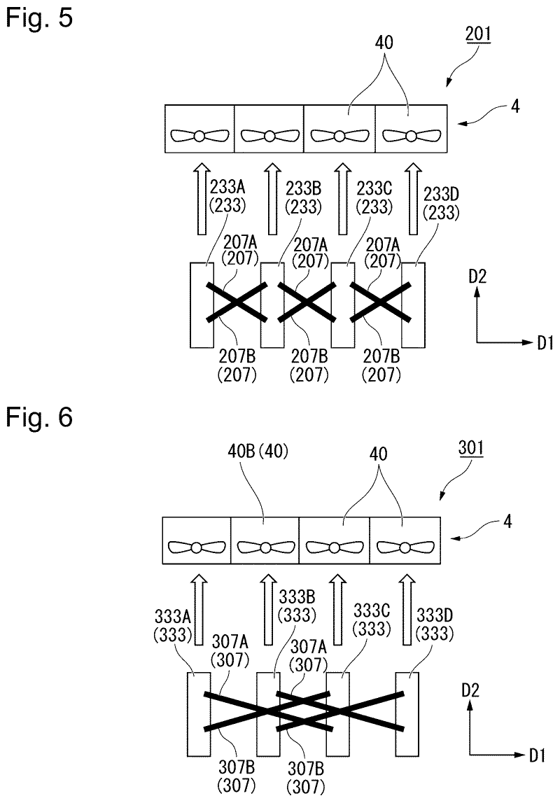

FIG. 5 is a diagram schematically illustrating a connection configuration between a plurality of heat pipes 207 and a plurality of heat sinks 233 of an electronic device 201 according to the third embodiment.

The electronic device 201 includes three first heat pipes 207A and three second heat pipes 207B as the plurality of heat pipes 207. In addition, the electronic device 201 includes, as the plurality of heat sinks 233, a first heat sink 233A, a second heat sink 233B, a third heat sink 233C, and a fourth heat sink 233D. The first heat sink 233A, the second heat sink 233B, the third heat sink 233C, and the fourth heat sink 233D are arranged in this order toward one side (+D side) in the first direction. Each heat sink 233 faces the fan 40 in the second direction.

The first heat pipe 207A and the second heat pipe 207B are connected to the pair of heat sinks 233 as a set including two heat pipes in total. One set includes one first heat pipe 207A and one second heat pipe 207B. In the electronic device 201 according to the present embodiment, three sets of heat pipes 207 are provided.

The first heat pipe 207A and the second heat pipe 207B of each set of heat pipes 207 are disposed so as to cross each other. Here, attention is paid to one set connecting the first heat sink 233A and the second heat sink 233B among the three sets. The first heat pipe 207A is connected to a region on one side (+D2 side) in the second direction of the first heat sink 233A and a region on the other side (−D2 side) in the second direction of the second heat sink 233B. In addition, the second heat pipe 207B is connected to a region on the other side (−D2 side) in the second direction of the first heat sink 233A and a region on one side (+D2 side) in the second direction of the second heat sink 233B.

The other set of the first heat pipe 207A and the second heat pipe 207B intersects and connects the second heat sink 233B and the third heat sink 233C. In still another set, the first heat pipe 207A and the second heat pipe 207B intersect and connect the third heat sink 233C and the fourth heat sink 233D.

The cooling device 4 generates an airflow toward one side (+D2 side) in the second direction in the housing 60. Therefore, in each heat sink 233, the temperature tends to be higher in the region on one side (+D2) in the second direction, which is the downstream side of the airflow, than in the region on the other side (−D2 side) in the second direction, which is the upstream side. According to the present embodiment, the heat pipes 207 connect the upstream region and the downstream region between the different heat sinks 233. As a result, the heat pipe 207 can promote heat transfer from the downstream side to the upstream side, reduce the temperature difference between the upstream side and the downstream side, and enhance the cooling efficiency of each heat sink 233.

FIG. 6 is a diagram schematically illustrating a connection configuration between a plurality of heat pipes 307 and the plurality of heat sinks 333 of an electronic device 301 according to the fourth embodiment.

The electronic device 301 includes, as the plurality of heat pipes 307, two first heat pipes 307A and two second heat pipes 307B. In addition, the electronic device 301 includes, as the plurality of heat sinks 333, a first heat sink 333A, a second heat sink 333B, a third heat sink 333C, and a fourth heat sink 333D. The first heat sink 333A, the second heat sink 333B, the third heat sink 333C, and the fourth heat sink 333D are arranged in this order toward one side (+D side) in the first direction. Each heat sink 333 faces the fan 40 in the second direction.

The first heat pipe 307A and the second heat pipe 307B are connected to the pair of heat sinks 333 as a set including two heat pipes in total. One set includes one first heat pipe 307A and one second heat pipe 307B. The electronic device 301 according to the present embodiment is provided with two sets of heat pipes 307.

The first heat pipe 307A and the second heat pipe 307B of each set of heat pipes 307 are disposed so as to cross each other. Here, attention is paid to one set connecting the first heat sink 333A and the third heat sink 333C among the two sets. The first heat pipe 307A is connected to a region on one side (+D2 side) in the second direction of the first heat sink 333A and a region on the other side (−D2 side) in the second direction of the third heat sink 333C. In addition, the second heat pipe 307B is connected to a region on the other side (−D2 side) in the second direction of the first heat sink 333A and a region on one side (+D2 side) in the second direction of the third heat sink 333C.

According to the present embodiment, similarly to the third embodiment, temperatures on the upstream side and the downstream side can be suppressed by connecting the upstream region and the downstream region between the different heat sinks 333 in which the heat pipes 307 are arranged in the first direction D1, and cooling efficiency in each heat sink 333 can be enhanced.

The other set of the first heat pipe 307A and the second heat pipe 307B intersects and connects the second heat sink 333B and the fourth heat sink 333D.

The heat pipe 307 of the electronic device 301 of the present embodiment connects two or more adjacent heat sinks 333 among three or more heat sinks 333 arranged in the first direction D1. When the air blowing amount of one fan 40B decreases, an airflow flows from the fan 40 adjacent to the one fan to the fan 40B side where the air blowing amount has decreased. Therefore, the air volume passing through the next fan 40 and the heat sink 333 facing in the second direction D2 decreases, and the cooling effect is reduced. According to the present embodiment, the heat pipe 307 can suppress insufficient cooling of the adjacent heat sink 333 by sending heat to the two or more heat sinks 333 away, and can enhance reliability of cooling as a whole.

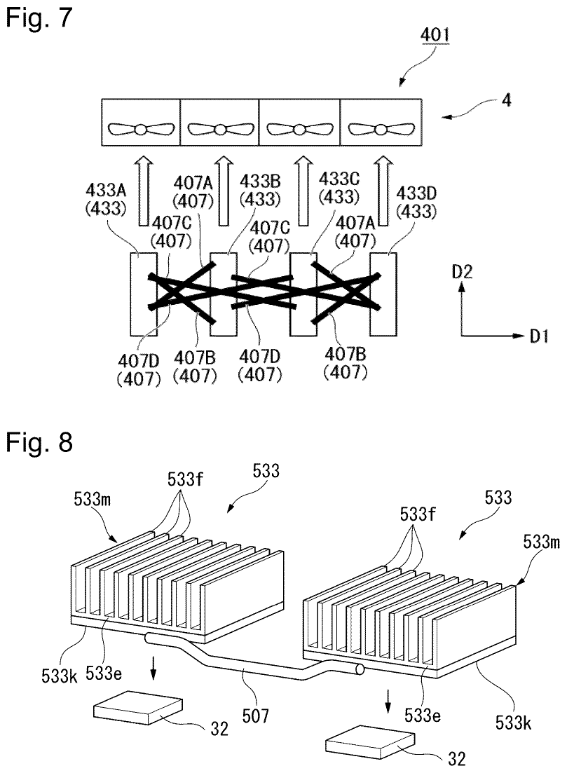

FIG. 7 is a diagram schematically illustrating a connection configuration between a plurality of heat pipes 407 and a plurality of heat sinks 433 of an electronic device 401 according to the fifth embodiment.

The electronic device 401 includes, as the plurality of heat pipes 407, two first heat pipes 407A, two second heat pipes 407B, two third heat pipes 407C, and two fourth heat pipes 407D. In addition, the electronic device 401 includes, as the plurality of heat sinks 433, a first heat sink 433A, a second heat sink 433B, a third heat sink 433C, and a fourth heat sink 433D. The first heat sink 433A, the second heat sink 433B, the third heat sink 433C, and the fourth heat sink 433D are arranged in this order toward one side (+D side) in the first direction. Each heat sink 433 faces the fan 40 in the second direction.

The first heat pipe 407A and the second heat pipe 407B have configurations similar to those of the first heat pipe 207A and the second heat pipe 207B described in the third embodiment (see FIG. 5). That is, the first heat pipe 407A and the second heat pipe 407B intersect and connect the two heat sinks 433 adjacent to each other.

The third heat pipe 407C and the fourth heat pipe 407D have configurations similar to those of the first heat pipe 307A and the second heat pipe 307B described in the fourth embodiment (see FIG. 6). That is, the third heat pipe 407C and the fourth heat pipe 407D intersect and connect two adjacent heat sinks 433.

According to the present embodiment, by incorporating the configurations of the heat pipes of the third embodiment and the fourth embodiment into one electronic device 401, the effects obtained by these configurations can be simultaneously obtained, and the reliability of the electronic device 401 can be further enhanced.

According to the electronic device 401 of the present embodiment, the electronic device includes three or more heat sinks 433, and at least two heat pipes 407 connected to at least two different heat sinks 433 are connected to at least one heat sink 433. According to the present embodiment, it is possible to provide the electronic device 401 in which redundancy of cooling is enhanced and reliability is further enhanced.

FIG. 8 is a perspective view of a heat sink 533 and a heat pipe 507 according to a sixth embodiment. Note that the configurations of the heat sink 533 and the heat pipe 507 of the present embodiment can also be adopted in the above-described embodiments.

The heat sink 533 of the present embodiment includes a main body 533m and a heat conduction plate 533k. The main body 533m includes a base plate 533e and a plurality of fins 533f protruding from one surface of the base plate 533e. The heat sink 533 is cooled by air passing between the fins 533f arranged in one direction.

The heat conduction plate 533k is joined to one surface of the base plate 533e. The heat conduction plate 533k is in contact with the heat element 32 directly or via a flowable heat transfer material such as heat radiation grease. The heat conduction plate 533k is, for example, a vapor chamber. The heat conduction plate 533k is connected to the heat pipes 507. When the heat conduction plate 533k is a vapor chamber, it is preferable that the heat conduction plate 533k and the heat pipe 507 share an internal working fluid.

According to the heat sink 533 and the heat pipe 507 of the present embodiment, heat transfer between the heat sinks 533 becomes smoother. For this reason, even when the amount of heat radiation in the specific heat sink 533 decreases, heat can be quickly transferred to the other heat sinks 533, and the reliability of cooling of the heat element 32 can be enhanced.

Although various embodiments of the present invention have been described above, configurations in the respective embodiments and combinations thereof are examples, and thus, addition, omission, replacement of configurations, and other modifications can be made within a range without departing from the spirit of the present invention. Also note that the present invention is not limited by the embodiment.

Note that the present technique can have a configuration below.
(1) An electronic device including: a plurality of heat elements; a plurality of heat sinks, at least one of which is attached to each of the heat elements; a cooling device that feeds a fluid in contact with a surface of the heat sink and promotes heat radiation of the heat sink by the fluid; and a heat pipe connected to the plurality of heat sinks.
(2) The electronic device according to (1), including: a first heat pipe and a second heat pipe as the plurality of heat pipes; and a first heat sink, a second heat sink, and a third heat sink as the plurality of heat sinks, in which the first heat pipe is connected to the first heat sink and the second heat sink, and the second heat pipe is connected to the second heat sink and the third heat sink.
(3) The electronic device according to (1), including: a first heat sink, a second heat sink, and a third heat sink as the plurality of heat sinks, in which one of the heat pipes is connected to the first heat sink, the second heat sink, and the third heat sink.
(4) The electronic device according to any one of (1) to (3), in which the cooling device includes a plurality of fans for sending air as the fluid, the plurality of fans are arranged in a first direction and generate an airflow in a second direction orthogonal to the first direction, and the heat sinks are arranged in the first direction.
(5) The electronic device according to (4), including: a first heat sink and a second heat sink arranged in the first direction as the plurality of heat sinks; and a first heat pipe and a second heat pipe as the plurality of heat pipes, in which the first heat pipe is connected to a region on one side in the second direction of the first heat sink and a region on an other side in the second direction of the second heat sink, and the second heat pipe is connected to a region on an other side in the second direction of the first heat sink and a region on one side in the second direction of the second heat sink.
(6) The electronic device according to (4) or (5), including: three or more of the heat sinks arranged in the first direction, in which the heat pipe connects two or more of the heat sinks adjacent to each other.
(7) The electronic device according to any one of (4) to (6), including: three or more of the heat sinks, in which at least two of the heat pipes connected to at least two of the heat sinks different from each other are connected to at least one of the heat sinks.
(8) The electronic device according to any one of (1) to (7), in which the heat sink includes a plurality of fins arranged in one direction, and the heat pipe extends along one direction and penetrates and is connected to the plurality of fins.
(9) The electronic device according to any one of (1) to (8), in which the heat sink includes a heat conduction plate that is in contact with the heat element, and the heat pipe is connected to the heat conduction plate.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electronic device comprising:
a plurality of heat elements;
a plurality of heat sinks, at least one of which is attached to each of the heat elements;
a cooling device that feeds a fluid in contact with a surface of the heat sink and promotes heat radiation of the heat sink by the fluid; and
a heat pipe connected to the plurality of heat sinks.

2. The electronic device according to claim 1, comprising:
a first heat pipe and a second heat pipe as the plurality of heat pipes; and
a first heat sink, a second heat sink, and a third heat sink as the plurality of heat sinks, wherein
the first heat pipe is connected to the first heat sink and the second heat sink, and
the second heat pipe is connected to the second heat sink and the third heat sink.

3. The electronic device according to claim 1, comprising:
a first heat sink, a second heat sink, and a third heat sink as the plurality of heat sinks, wherein
one of the heat pipes is connected to the first heat sink, the second heat sink, and the third heat sink.

4. The electronic device according to claim 1, wherein
the cooling device includes a plurality of fans for sending air as the fluid,
the plurality of fans are arranged in a first direction and generate an airflow in a second direction orthogonal to the first direction, and
the heat sinks are arranged in the first direction.

5. The electronic device according to claim 4, comprising:
a first heat sink and a second heat sink arranged in the first direction as the plurality of heat sinks; and
a first heat pipe and a second heat pipe as the plurality of heat pipes, wherein
the first heat pipe is connected to a region on one side in the second direction of the first heat sink and a region on an other side in the second direction of the second heat sink, and
the second heat pipe is connected to a region on an other side in the second direction of the first heat sink and a region on one side in the second direction of the second heat sink.

6. The electronic device according to claim 4, comprising:
three or more of the heat sinks arranged in the first direction, wherein
the heat pipe connects two or more of the heat sinks adjacent to each other.

7. The electronic device according to claim 4, comprising:
three or more of the heat sinks, wherein
at least two of the heat pipes connected to at least two of the heat sinks different from each other are connected to at least one of the heat sinks.

8. The electronic device according to claim 1, wherein
the heat sink includes a plurality of fins arranged in one direction, and
the heat pipe extends along one direction and penetrates and is connected to the plurality of fins.

9. The electronic device according to claim 1, wherein
the heat sink includes a heat conduction plate that is in contact with the heat element, and
the heat pipe is connected to the heat conduction plate.
